(19) United States
(12) Patent Application Publication
(10) Pub. No.: US 2024/0231313 A1
(43) Pub. Date: Jul. 11, 2024

(54) INFORMATION DISPLAYING METHOD AND COMPUTER PROGRAM PRODUCT FOR SEMICONDUCTOR MANUFACTURING APPARATUS

(71) Applicant: EBARA CORPORATION, Tokyo (JP)

(72) Inventors: Kosei TAKEUCHI, Tokyo (JP); Masayuki FUJIKI, Tokyo (JP)

(21) Appl. No.: 18/529,730

(22) Filed: Dec. 5, 2023

(30) Foreign Application Priority Data
Jan. 10, 2023 (JP) 2023-001761

(51) Int. Cl. G05B 19/4099

(52) U.S. Cl. CPC G05B 19/4099; G05B 2219/45031

(57) ABSTRACT

An object of the invention is to make a tangible calculation condition in calculation processing, that is applied to measured data, be able to be checked in a semiconductor manufacturing apparatus. A method for displaying information in a semiconductor manufacturing apparatus comprises steps for: obtaining a single piece or plural pieces of time-series measured data relating to processing of a substrate in the semiconductor manufacturing apparatus; obtaining one or plural statistical values by applying statistical processing to the single piece or plural pieces of time-series measured data; based on selection of a single statistical value from the one or plural statistical values, identifying a statistical processing condition that was used in statistical processing performed for obtaining the selected single statistical value; and displaying the identified statistical processing condition.

### TECHNICAL FIELD

The present invention relates to an information displaying method and a computer program product used in a semiconductor manufacturing apparatus.

### BACKGROUND ART

In a semiconductor manufacturing apparatus, a technique, wherein various kind of data are measured during processing of a substrate and the above measured data are displayed on a computer screen during processing or thereafter, has been practiced. Further, a technique for displaying data (for example, an average value), that is obtained as a result that a calculation process is applied to measured data, has been practiced.

### CITATION LIST

### Patent Literature

PTL 1: Japanese Patent Application Public Disclosure No. 2021-150540

### SUMMARY OF INVENTION

### Technical Problem

As explained above, in the case that a calculation process is applied to measured data, there is a demand that tangible calculation conditions with respect to the calculation process be made to be able to be checked.

### Solution to Problem

(Mode 1) According to mode 1, a method for displaying information in a semiconductor manufacturing apparatus is provided, wherein the method comprises steps for: obtaining a single piece or plural pieces of time-series measured data relating to processing of a substrate in the semiconductor manufacturing apparatus; obtaining one or plural statistical values by applying statistical processing to the single piece or plural pieces of time-series measured data; based on selection of a single statistical value from the one or plural statistical values, identifying a statistical processing condition that was used in statistical processing performed for obtaining the selected single statistical value; and displaying the identified statistical processing condition.

(Mode 2) According to mode 2 that comprises the method in mode 1, the step for obtaining the one or plural statistical values comprises steps for reading the statistical processing condition from a setting file in which the statistical processing condition used for calculating the statistical value from the time-series measured data has been described, and calculating the statistical value from the time-series measured data, by using the statistical processing condition read from the setting file; and the step for identifying the statistical processing condition comprises a step for obtaining, from the setting file, the statistical processing condition corresponding to the statistical processing used for obtaining the selected single statistical value.

(Mode 3) According to mode 3 that comprises the method in mode 1, the method further comprises a step for displaying, in a selectable manner, the one or plural statistical values.

(Mode 4) According to mode 4 that comprises the method in mode 3, display of the one or plural statistical values includes display for showing whether each of the one or plural statistical values is abnormal.

(Mode 5) According to mode 5 that comprises the method in mode 1, the step for displaying the identified statistical processing condition comprises a step for displaying, on a single screen, the identified statistical processing condition and the time-series measured data corresponding to the selected single statistical value.

(Mode 6) According to mode 6 that comprises the method in mode 2, the method further comprises steps for receiving correction with respect to the displayed statistical processing condition, and updating the setting file based on the correction.

(Mode 7) According to mode 7 that comprises the method in mode 1, the statistical processing condition comprises at least one of i) a calculation formula that is used when performing the statistical processing and ii) a data range of the time-series measured data that are determined as objects of the statistical processing.

(Mode 8) According to mode 8 that comprises the method in mode 7, displaying the statistical processing condition comprises displaying each of the calculation formula and the data range as that having one of a mathematically represented form and a program code form.

(Mode 9) According to mode 9, a computer program product is provided, wherein the computer program product comprises computer executable instructions constructed to make a computer implement the method in any one of modes 1-8 when the computer executable instructions are executed by a processor in the computer.

### BRIEF DESCRIPTION OF DRAWINGS

FIG. 1 is a general layout drawing of a plating apparatus relating to an embodiment of the present invention.

FIG. 2 is a schematic cross-sectional side view of a plating module.

FIG. 3 is a configuration diagram of an example system used for implementing a method according to an embodiment of the present invention.

FIG. 4 is a flow chart showing operation of a system used for implementing a method according to an embodiment of the present invention.

FIG. 5 is a figure showing examples of time-series measured data.

FIG. 6 is an example of screen display showing statistical values.

FIG. 7A is an example of screen display showing a statistical process condition.

FIG. 7B is an example of screen display showing a statistical process condition.

FIG. 7C is an example of screen display showing a statistical process condition.

FIG. 7D is an example of screen display showing a statistical process condition.

### DESCRIPTION OF EMBODIMENTS

In the following description, embodiments of the present invention will be explained with reference to the figures. In the figures which will be explained below, a reference symbol that is the same as that assigned to one component is assigned to the other component which is the same as or corresponds to the one component, and overlapping explanation of these components will be omitted.

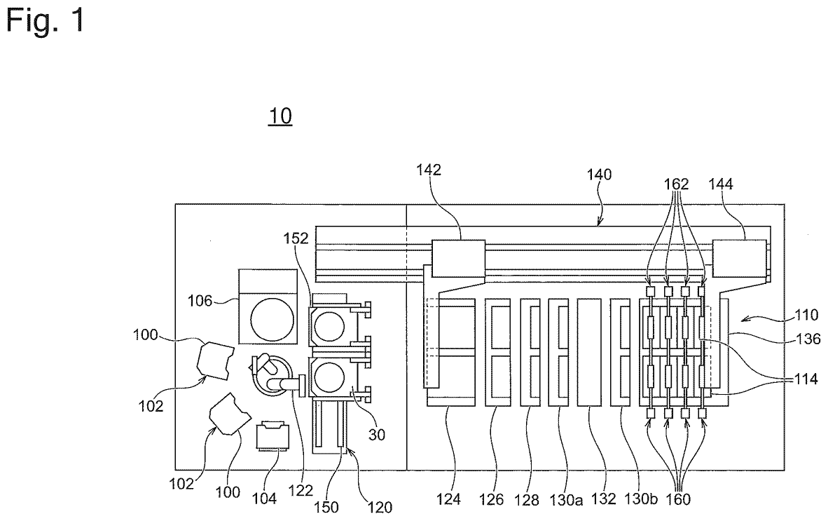

FIG. 1 is a general layout drawing of a plating apparatus 10 relating to an embodiment of the present invention. Although an embodiment of the present invention will be explained with reference to the plating apparatus 10 in the following description, the method according to the embodiment of the present invention can be applied to semiconductor manufacturing apparatuses other than a plating apparatus (for example, a CMP (Chemical Mechanical Polishing) apparatus and so on).

As shown in FIG. 1, the plating apparatus 10 comprises: two cassette tables 102; an aligner 104 for aligning, in a predetermined direction, a position of an orientation flat, a notch, or the like of a substrate; and a spin rinse dryer 106 for drying, after completion of a plating process of a substrate, the substrate by rotating it at high speed. A cassette 100, in which a substrate such as a semiconductor wafer or the like is housed, is loaded onto the cassette table 102. A load/unload station 120, onto which a substrate holder 30 is loaded to attach/detach a substrate thereto/therefrom, is installed in a position close to the spin rinse dryer 106. In a position in the center of the above units 100, 104, 106, and 120, a transfer robot 122 which carries a substrate between the above units is arranged.

The load/unload station 120 comprises loading plates 152, wherein each loading plate 152 has a flat plate shape and is able to slide in a lateral direction along rails 150. Two substrate holders 30 are loaded, in parallel with each other in a horizontal state, onto the loading plates 152; and, after completion of delivery of a substrate between one of the substrate holders 30 and the transfer robot 122, the loading plates 152 are slid in a lateral direction, and delivery of a substrate between the other of the substrate holders 30 and the transfer robot 122 is performed.

The plating apparatus 10 further comprises a stocker 124, a pre-wet module 126, a pre-soak module 128, a first rinse module 130a, a blow module 132, a second rinse module 130b, and a plating module 110. In the stocker 124, storing and temporary storing of a substrate holder 30 is performed. In the pre-wet module 126, a substrate is soaked in pure water. In the pre-soak module 128, an oxide film on a surface of an electrically conducting layer such as a seed layer or the like formed on a surface of a substrate is removed by etching. In the first rinse module 130a, a substrate is rinsed together with a substrate holder 30 by using a cleaning solution (pure water or the like) after pre-soaking. In the blow module 132, liquid removal of a substrate is performed after rinsing. In the second rinse module 130b, a plated substrate is rinsed together with a substrate holder 30 by using a cleaning solution. The load/unload station 120, the stocker 124, the pre-wet module 126, the pre-soak module 128, the first rinse module 130a, the blow module 132, the second rinse module 130b, and the plating module 110 are arranged in the above listed order.

For example, the plating module 110 is constructed in such a manner that plural plating tanks 114 are housed in the inside of an overflow tank 136. In the example of FIG. 1, the plating module 110 comprises eight plating tanks 114. Each plating tank 114 is constructed in such a manner that it receives a single substrate in the inside thereof, soaks the substrate in plating liquid held in the inside thereof, and applies plating such as copper plating or the like to a surface of the substrate.

The plating apparatus 10 comprises a transfer apparatus 140 which is arranged in a position on a side of the above respective devices, adopts, for example, a linear motor system, and conveys a substrate holder 30, together with a substrate, between the above respective devices. The transfer apparatus 140 comprises a first transfer apparatus 142 and a second transfer apparatus 144. The first transfer apparatus 142 is constructed to convey a substrate between the load/unload station 120, the stocker 124, the pre-wet module 126, the pre-soak module 128, the first rinse module 130a, and the blow module 132. The second transfer apparatus 144 is constructed to convey a substrate between the first rinse module 130a, the second rinse module 130b, the blow module 132, and the plating module 110. The plating apparatus 10 may be constructed in such a manner that it does not comprise the second transfer apparatus 144, i.e., it comprises the first transfer apparatus 142 only.

In positions on both sides of the overflow tank 136, paddle drivers 160 and paddle followers 162 are arranged, wherein each of the paddle drivers 160 and each of the paddle followers 162 drive a paddle which is arranged in each of the plating tanks 114 and works as a stirring rod for stirring plating liquid in the plating tank 114.

An example of a series of plating processes performed by the plating apparatus 10 will be explained. First, a substrate is taken out by the transfer robot 122 from the cassette 100 loaded on the cassette table 102, and the substrate is conveyed to the aligner 104. The aligner 104 aligns, in a predetermined direction, a position of an orientation flat, a notch, or the like. The substrate, that has been aligned with respect to the direction by the aligner 104, is conveyed by the transfer robot 122 to the load/unload station 120.

Regarding the load/unload station 120, two substrate holders 30, which have been stored in the stocker 124, are gripped at the same time by the first transfer apparatus 142 in the transfer apparatus 140, and conveyed to the load/unload station 120. Thereafter, the two substrate holders 30 are put, at the same time and horizontally, on the loading plates 152 in the load/unload station 120. In the above state, the transfer robot 122 conveys the substrates to the substrate holders 30, respectively, and the conveyed substrates are held in the substrate holders 30, respectively.

Next, the two substrate holders 30, which hold the substrates, are gripped at the same time by the first transfer apparatus 142 in the transfer apparatus 140, and housed in the pre-wet module 126. Next, the substrate holders 30, which hold the substrates processed in the pre-wet module 126, are conveyed to the pre-soak module 128 by the first transfer apparatus 142, and, in the pre-soak module 128, an etching process is applied to an oxide film on each of the substrates. Following thereto, the substrate holders 30, which hold the above substrates, are conveyed to the first rinse module 130a, and the surfaces of the substrates are rinsed by pure water stored in the first rinse module 130a.

The substrate holders 30, which hold the substrates with respect to which the rinsing process applied thereto has been completed, are conveyed from the first rinse module 130a to the plating module 110 by the second transfer apparatus 144, and housed in the plating tanks 114 which have been filled with plating liquid. The second transfer apparatus 144 repeats the above procedures sequentially to thereby sequentially house the substrate holders 30, which hold substrates, in the plating tanks 114 in the plating module 110, respectively.

In each of the plating tanks 114, a surface of the substrate is plated by supplying plating electric current between the substrate and an anode (not shown in the figure) in the plating tank 114, and, at the same time, moving the paddle forward and backward, in parallel with the surface of the substrate, by the paddle driver 160 and the paddle follower 162.

After completion of plating, two substrate holders 30, which hold the plated substrates, are gripped at the same time by the second transfer apparatus 144, and conveyed to the second rinse module 130b, and the surfaces of the substrates are rinsed by pure water by soaking them in the pure water stored in the second rinse module 130b. Next, the substrate holders 30 are conveyed to the blow module 132 by the second transfer apparatus 144, and water droplets remaining on the substrate holders 30 are removed by air-blowing or the like. Thereafter, the substrate holders 30 are conveyed to the load/unload station 120 by the first transfer apparatus 142.

In the load/unload station 120, the processed substrate is taken out from the substrate holder 30 by the transfer robot 122, and conveyed to the spin rinse dryer 106. The spin rinse dryer 106 rotates, at high speed, the plated substrate to thereby dry it. The dried substrate is returned to the cassette 100 by the transfer robot 122.

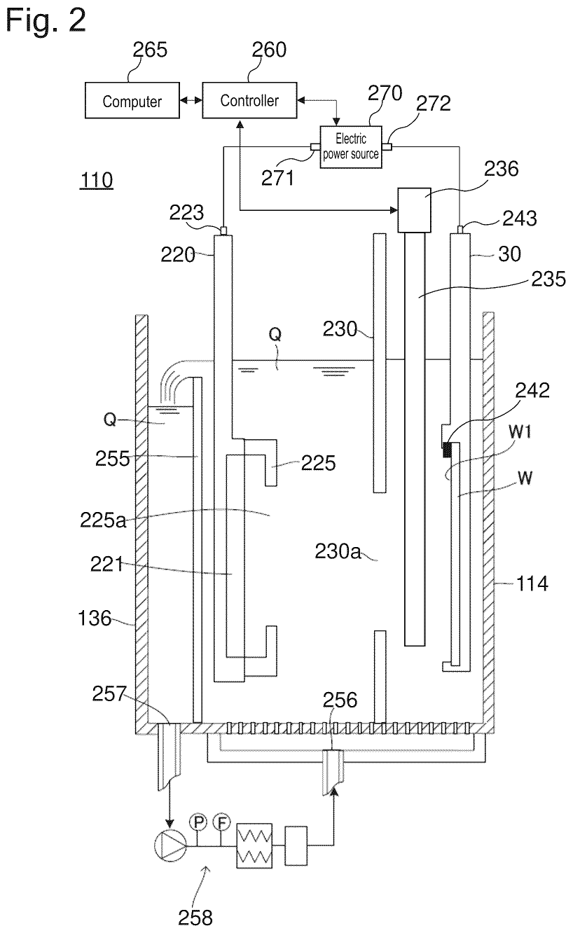

FIG. 2 is a schematic cross-sectional side view of the above-explained plating module 110. As shown in the figure, the plating module 110 comprises an anode holder 220 which is constructed to hold an anode 221, the substrate holder 30 which is constructed to hold a substrate W, the plating tank 114 which stores plating liquid Q including an additive, and an overflow tank 136 which receives and discharges a quantity of plating liquid Q overflowed from the plating tank 114. The plating tank 114 and the overflow tank 136 are separated from each other by a partition wall 255. The anode holder 220 and the substrate holder 30 are housed in the inside of the plating tank 114. As explained above, the substrate holder 30 holding the substrate W is conveyed by the second transfer device 144 (refer to FIG. 1) and housed in the plating tank 114.

In this regard, although a single plating tank 114 only is drawn in FIG. 2, the plating module 110 may be that comprising plural plating tanks 114 as explained above, wherein each of the plating tanks 114 may be that comprising the construction shown in FIG. 2.

The anode 221 is electrically connected to a positive terminal 271 of an electric power source 270 via an electric terminal 223 installed on the anode holder 220. The substrate W is electrically connected to a negative terminal 272 of the electric power source 270, via an electric contact 242 which is in contact with a periphery of the substrate W and an electric terminal 243 installed on the substrate holder 30. The electric power source 270 is constructed in such a manner that it supplies plating electric current between the anode 221 connected to the positive terminal 271 and the substrate W connected to the negative terminal 272, and also measures a voltage applied between the positive terminal 271 and the negative terminal 272.

Further, the electric power source 270 is connected to a controller 260 which controls operation of the electric power source 270, and the controller 260 is connected to a computer 265. The computer 265 provides a user interface for an operator of the plating apparatus 10. The operator of the plating apparatus 10 can input, via the computer 265, various kinds of setting information relating to plating processes. For example, the setting information includes a set value of plating electric current outputted from the electric power source 270. The controller 260 makes the electric power source 270 operate in accordance with a plating-electric-current set value inputted by the operator. Further, the controller 260 provides the computer 256 with status information that is based on information of a voltage that is applied between the terminals 271 and 272 and measured by the electric power source 270. The operator of the plating apparatus 10 can receive the status information via the computer 265. The controller 260 may be constructed in such a manner that it controls operation of respective parts other than the electric power source 270 in the plating module 110, or respective units other than the plating module 110 in the plating apparatus 10, and provides the computer 265 with various kinds of status information relating to above operation.

The anode holder 220 holding the anode 221 and the substrate holder 30 holding the substrate W are soaked in the plating liquid Q in the plating tank 114, and arranged to face with each other in such a manner that the anode 220 and the to-be-plated surface W1 of the substrate W are positioned in virtually parallel with each other. In the state that the anode 221 and the substrate W are being soaked in the plating liquid Q in the plating tank 114, the plating electric current is supplied from the electric power source 270 to them. As a result, metal ions in the plating liquid Q are deoxidized on the to-be-plated surface W1 of the substrate W, and a film is formed on the to-be-plated surface W1.

The anode holder 220 comprises an anode mask 225 for adjusting an electric field between the anode 221 and the substrate W. The anode mask 225 is a member which is virtually tabular and comprises dielectric material, for example, and installed on a front surface side of the anode holder 220 (a surface on a side facing the substrate holder 30). That is, the anode mask 225 is positioned between the anode 221 and the substrate holder 30. The anode mask 225 comprises a first opening 225a which is positioned in the virtually central part of the anode mask 225, and through which the electric current flowing between the anode 221 and the substrate W passes. It is preferable that the diameter of the opening 225a be smaller than the diameter of the anode 221. The anode mask 225 may be constructed in such a manner that the diameter of the opening 225a is adjustable.

The plating module 110 further comprises a regulation plate 230 for adjusting the electric field between the anode 221 and the substrate W. The regulation plate 230 is a member which is virtually tabular and comprises dielectric material, for example, and arranged in a position between the anode mask 225 and the substrate holder 30 (the substrate W). The regulation plate 230 comprises a second opening 230a, through which the electric current flowing between the anode 221 and the substrate W passes. It is preferable that the diameter of the opening 230a be smaller than the diameter of the substrate W. The regulation plate 230 may be constructed in such a manner that the diameter of the opening 230a is adjustable.

A paddle 235 is arranged in a position between the regulation plate 230 and the substrate W, for stirring the plating liquid Q existing in a region near the to-be-plated surface W1 of the substrate W. The paddle 235 is a member having a virtually rod shape, and arranged in the plating tank 114 in such a manner that it extends in a vertical direction. One of ends of the paddle 235 is fixed to the paddle driving device 236. Operation of the paddle driving device 236 is controlled by the controller 260, and the paddle 235 is moved horizontally by the paddle driving device 236 in a direction along the to-be-plated surface W1 of the substrate W. The plating liquid Q is stirred thereby.

The plating tank 114 comprises a plating liquid supply port 256 for supplying the plating liquid Q to the inside of the tank. The overflow tank 136 comprises a plating liquid exhaust port 257 for discharging a quantity of plating liquid Q overflowed from the plating tank 114. The plating liquid supply port 256 is arranged in a position on the bottom of the plating tank 114, and the plating liquid exhaust port 257 is arranged in a position on the bottom of the overflow tank 136.

When the plating liquid Q is being supplied from the plating liquid supply port 256 to the plating tank 114, a quantity of plating liquid Q overflows from the plating tank 114, and flows into the overflow tank 136 over the partition wall 255. The plating liquid Q flown into the overflow tank 136 is discharged from the plating liquid exhaust port 257, and impurities therein are removed by a filter or the like included in a plating liquid circulating device 258. The plating liquid Q, from which the impurities have been removed, is supplied to the plating tank 114 by the plating liquid circulating device 258 via the plating liquid supply port 256.

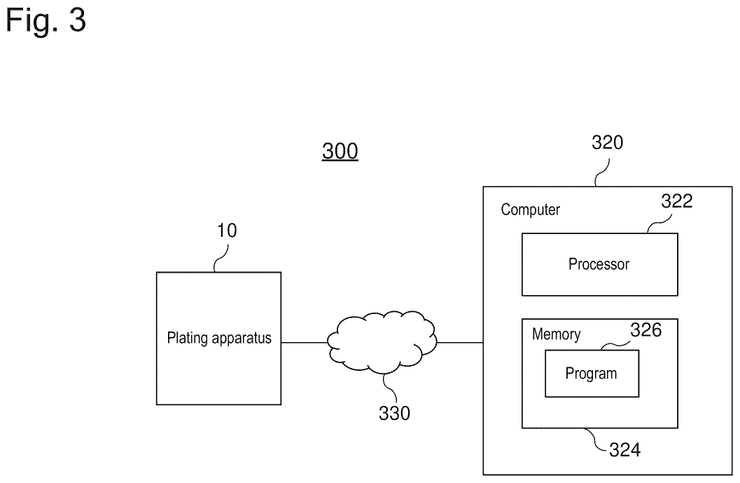

FIG. 3 is a configuration diagram of an example system 300 used for implementing a method according to an embodiment of the present invention. The system 300 comprises a plating apparatus 10 and a computer 320. The plating apparatus 10 is the plating apparatus which was explained with reference to FIG. 1 or 2. The plating apparatus 10 and the computer 320 are communicably connected with each other via a network 330 such as a LAN (local area network), the Internet, or the like. In a different construction, the computer 320 may be incorporated in the plating apparatus 10 as a part of the construction of the plating apparatus 10. The computer 320 comprises a processor 322 and a memory 324. The memory 324 stores a program 326 which realizes a method according to an embodiment of the present invention. The processor 322 reads the program 326 from the memory 324 and executes it. As a result, the system 300 is made to be able to implement the method according to an embodiment of the present invention. In this regard, although a single computer 320 only is shown in FIG. 3, the system 300 may comprise plural computers 320. In the case of the above construction, memories 324 in the computers 320 may store programs corresponding to parts of the method according to an embodiment of the present invention, respectively; and the processors 322 in the computers 320 may execute the programs, respectively, in such a manner that plural computers 320 cooperate with one another to implement, as a whole, the method according to an embodiment of the present invention.

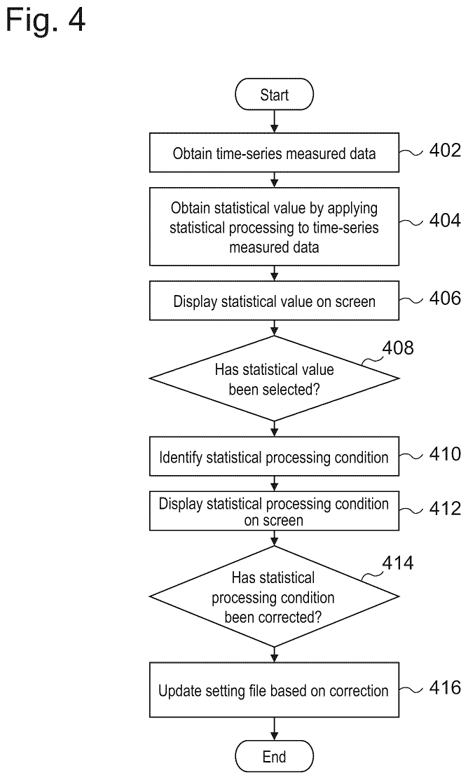

FIG. 4 is a flow chart showing operation of the system 300 used for implementing a method according to an embodiment of the present invention. The processes in the respective steps in the flow chart in FIG. 4 are performed by the processor 322 in the computer 320. The method according to the embodiment relating to FIG. 4 starts from step 402.

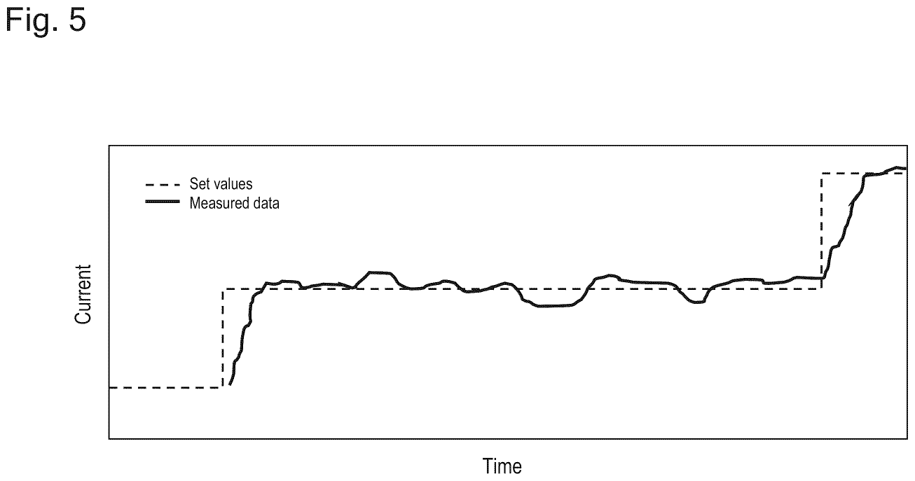

In step 402, the processor 322 obtains a single piece or plural pieces of time-series measured data relating to processing of a substrate in the plating apparatus 10. For example, the processor 322 obtains, from the controller 260 (refer to FIG. 2) which has been installed along with the plating module 110, time-series measured data relating to plating processing applied to a substrate. Example time-series measured data obtained from the controller 260 include measured data of values of current or a voltage outputted from the electric power source 270, or measured data of speed of stirring by the paddle 235 driven by the paddle driving device 236. FIG. 5 shows, as examples of time-series measured data, examples of measured data of values of current outputted from the electric power source 270. Other examples of time-series measured data include temperature of the plating liquid Q in the plating tank 114, and measured data of any physical quantities measured in the plating module 110 or other modules.

Next, in step 404, the processor 322 calculates one or plural statistical values by applying statistical processing to the respective time-series measured data. For example, the processor 322 calculates statistical values, such as values of average current, accumulated current, and so on, from time-series measured data of output current of the electric power source 270. The statistical processing is not limited to processing for averaging and accumulating, and includes any statistical calculation processing. Tangible calculation procedures of the statistical processing (hereinafter, they will be referred to as “statistical processing conditions”) may be described in a predetermined setting file, for example. In the setting file, definitions (statistical processing conditions) that represent how respective statistical values are calculated, specifically, time-series measured data that are to be used and the types of calculation processing that are to be performed for calculating the respective statistical values, are described. For example, a statistical processing condition exemplified below is described in the setting file: Average current of the electric power source 270 (i.e., a statistical value relating to output current of the electric power source 270) is a value obtained by performing time-averaging of time-series measured data of output current of the electric power source 270 obtained during a designated time range spanning from specific start time to specific end time. In an embodiment, a setting file such as that explained above is stored in advance in a storage device (for example, the memory 324) in the computer 320. The processor 322 may read, from the setting file, respective statistical processing conditions relating to respective statistical values, and, in accordance with the read respective statistical processing conditions, calculate the respective statistical values.

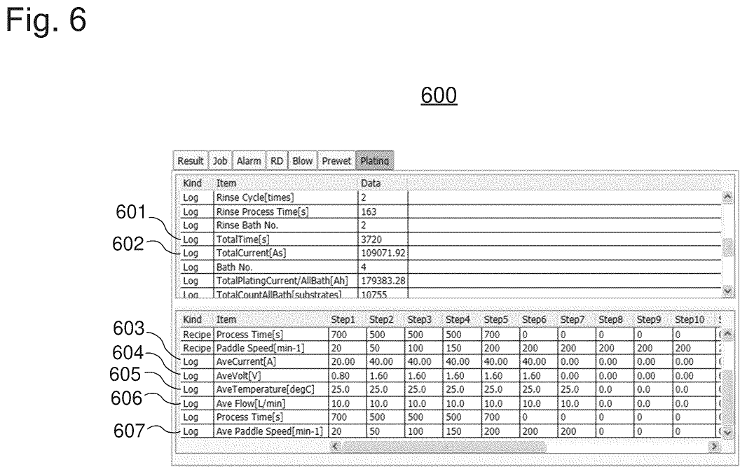

Next, in step 406, the processor 322 performs operation for displaying, on a screen of the computer 320, the respective statistical values calculated in step 404. FIG. 6 is an example of screen display of calculated statistical values. In the example, a display careen 600 includes, as various kinds of statistical values relating to plating processing in the plating module 100, a processing time 601, an accumulated current quantity 602, an average current value 603, an average voltage value 604, an average temperature 605, an average flow rate 606, and an average stirring speed 607. Each of the statistical values on the screen is displayed in such a manner that an input for selecting the statistical value is allowed to be entered by an operator of the computer 320. For example, an operator of the computer 320 can indicate, to the computer 320, an event that the operator has selected, by performing a mouse click manipulation or the like in an area corresponding to the average current value 603 on the screen, one of statistical values (the average current value in this example) from the plural statistical values displayed on the screen.

In this regard, in the display screen 600, each of the statistical values may be displayed in a mode that allows discrimination as to whether the value is abnormal. For example, in the case that a statistical value is judged to be abnormal based on comparison of it with a predetermined reference value (for example, a set value described in recipe information that defines various process conditions relating to a substrate in the plating apparatus 10), the statistical value may be highlighted when it is displayed. An operator of the computer 320 may be directed by highlight to pay attention thereto, and may select the highlighted statistical value on the screen 600.

Next, in step 408, the processor 322 performs judgment as to whether action for selecting a statistical value on the screen of the computer 320 has been performed and completed. In the case that action for selecting a statistical value has been completed, the process proceeds to step 410, and the processor 322 identifies a statistical processing condition that was used when calculating the selected statistical value, and, in step 412 that follows the above step, makes the identified statistical processing condition be displayed on the screen of the computer 320. The above-explained setting file is used when identifying a statistical processing condition. The processor 322 is able to obtain, from the setting file in which respective statistical processing conditions relating to respective statistical values (i.e., respective definitions of calculation procedures for respective statistical values) have been described, a statistical processing condition corresponding to the statistical value selected in step 408.

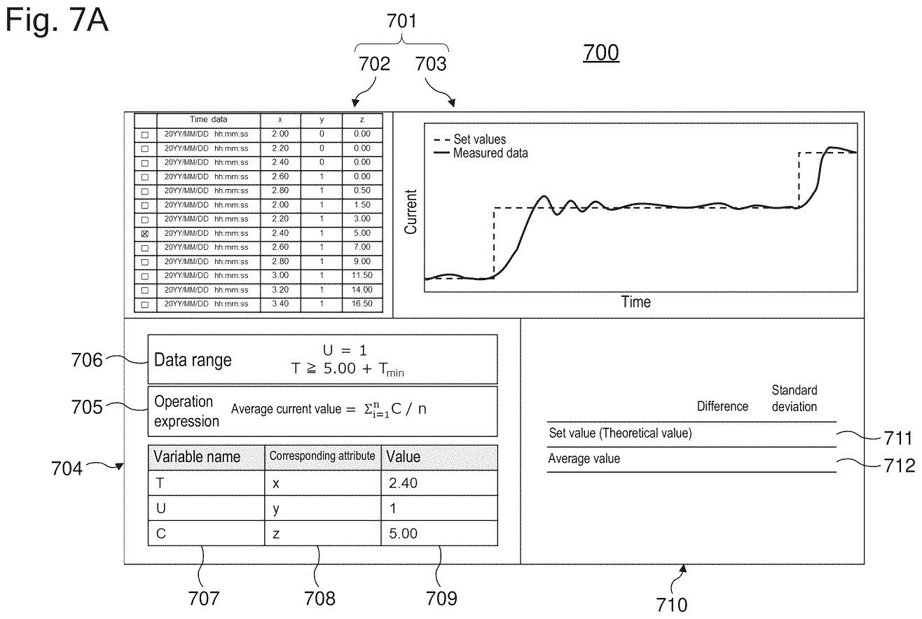

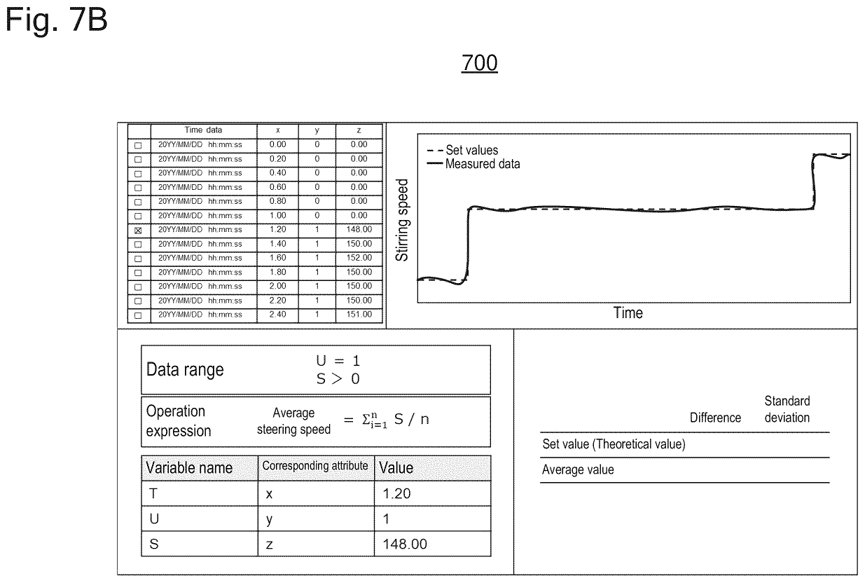

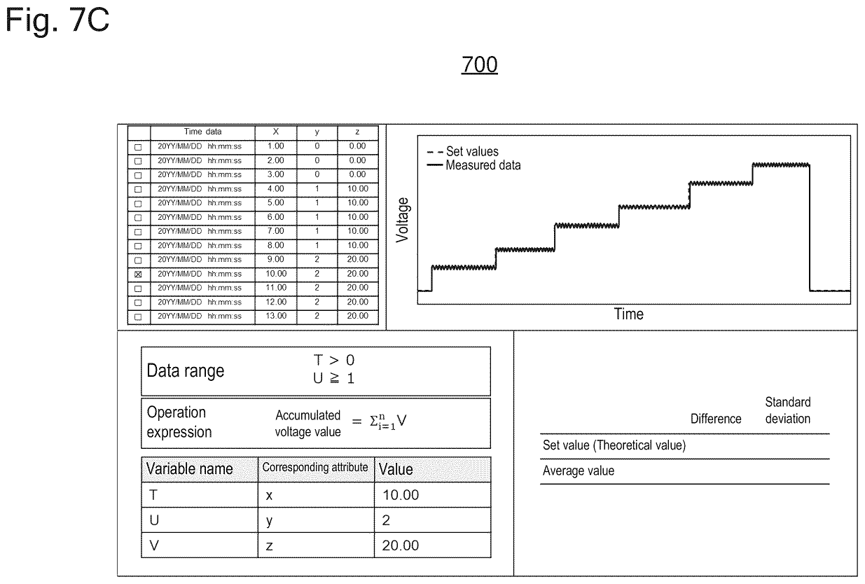

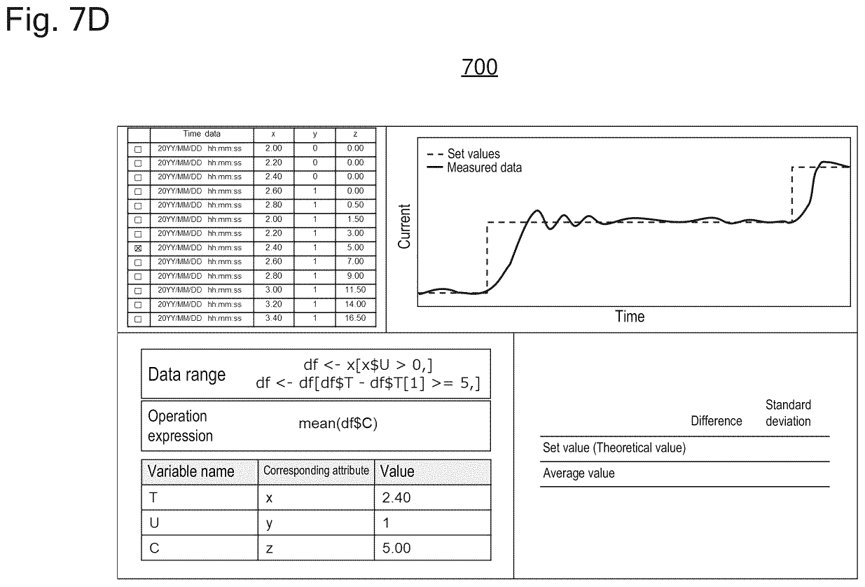

Each of FIGS. 7A-7D is an example of screen display of a statistical process condition in step 412. FIG. 7A shows an display example of a statistical processing condition in the case that the statistical value is an average current value of current outputted from the electric power source 270 in the plating module 110. As shown in FIG. 7A, the display screen 700 for a statistical processing condition comprises a time-series measured data display area 701, a statistical processing condition display area 704, and a statistical value evaluation area 710. The time-series measured data display area 701 and the statistical value evaluation area 710 may be omitted. The time-series measured data display area 701 comprises a list display area 702 and a graph display area 703. In the list display area 702, time-series measured data (measured data of output current of the electric power source 270 in this example) corresponding to a statistical value that is the object of display on the screen 700 (that is, the statistical value selected in step 408; An average current value of the electric power source 270 in the example in FIG. 7A) are displayed as numerical values, and the numerical values are arranged in the form of a list. Specifically, each row in the list display area 702 corresponds to measured data obtained at a specific point in time, and a column “x” represents measurement time and a column “z” represents measured values. The graph display area 703 displays, in the form of a graph, the values in the list display area 702.

The statistical processing condition identified in step 410 is displayed in the statistical processing condition display area 704 in the screen 700. In the statistical processing condition display area 704, an operation expression 705 represents an operation expression used for calculating a statistical value (an average current value of the electric power source 270 in FIG. 7A), and a data range 706 represents a range of measured data that are selected as calculation objects for statistical-value calculation based on the operation expression 705. The variables (T, U, and C) relating to the operation expression 705 and the data range 706 are related, based on correspondence relationship shown by a variable name 707 and an attribute 708, to the attributes (x, y, and z) in the list display area 702. Specifically, in the example in FIG. 7A, measured data, with respect to each of those the value in the column “y” in the list display area 702 is 1 and the point in time when that was measured is a point in time after 5.00 seconds has elapsed since the time represented by a predetermined value Tₘᵢₙ, are selected as objects of a summation Σ in the operation expression 705. The predetermined value Tₘᵢₙ may be defined as the time when the output current value has reached, for the first time, a current value that is 90% of a predetermined set current value, for example. In this regard, a value 709 shows numerical values in a row, with respect to which a checkbox added thereto has been checked, in the list display area 702.

By displaying a statistical processing condition including the operation expression 705 and the data range 706 in the manner explained above, it becomes easy, for an operator of the computer 320, to grasp a calculation procedure that was used when calculating a statistical value obtained in relation to processing of a substrate in the plating apparatus 10. For example, by clicking the part of the average current value 603 in the screen 600 in FIG. 6, an operator of the computer 320 can make a statistical processing condition, that is used for calculating an average current value from measured data of plating current, be displayed on a screen 700 such as that shown in FIG. 7A.

In addition, in the statistical value evaluation area 710, a difference between a calculated statistical value and a set value in the recipe information and/or a standard deviation 711, and a difference between a statistical value obtained in relation to present operation and a history statistical value obtained during operation of the plating apparatus 10 in the past and/or a standard deviation 712 are displayed.

Each of FIGS. 7B and 7C shows an example of screen display similar to that explained above. FIG. 7B shows a display example of a statistical processing condition in the case that the statistical value is average stirring speed of the paddle 235 in the plating module 110. FIG. 7C shows a display example of a statistical processing condition in the case that the statistical value is an accumulated voltage value of the voltage outputted from the electric power source 270 in the plating module 110. In each of the three display examples in FIGS. 7A-7C, contents of the statistical processing condition (the operation expression 705 and the data range 706) are shown as those having mathematically represented forms. However, the form for representing the statistical processing condition is not limited to those explained above. In a manner similar to that in a screen display example in FIG. 7D, contents of the statistical processing condition (the operation expression 705 and the data range 706) may be displayed as those having program code forms.

Next, in step 414, the processor 322 performs judgment as to whether correction of the statistical processing condition has been performed and completed on the screen 700. In the case that correction of the statistical processing condition has been completed, the process proceeds to step 416, and the processor 322 updates, based on correction, the statistical processing condition described in the setting file. For example, there may be a case that a statistical processing condition in the setting file stored in a storage device (for example, the memory 324) in the computer 320 is inappropriate in view of an actual operation environment and/or an operation state of the plating apparatus 10. In such a case, an operator of the computer 320 may enter an input for correcting the statistical processing condition on the screen 700, and, in accordance with the input, the statistical processing condition described in the setting file is updated to an appropriate version thereof. As a result, it becomes possible to calculate a statistical value in step 404 by using an appropriate statistical processing condition, when the flow chart in FIG. 4 is executed next time.

In the above description, embodiments of the present invention have been explained based on some examples; and, in this regard, the above-explained embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

### REFERENCE SIGNS LIST

10 Plating apparatus
30 Substrate holder
100 Cassette
102 Cassette table
104 Aligner
106 Spin rinse dryer
110 Plating module
114 Plating tank
120 Load/unload station
122 Transfer robot
124 Stocker
126 Pre-wet module
128 Pre-soak module
130a First rinse module
130b Second rinse module
132 Blow module
136 Overflow tank
140 Transfer apparatus
142 First transfer apparatus
144 Second transfer apparatus
150 Rail
152 Loading plate
160 Paddle driver
162 Paddle follower
300 System
320 Computer
322 Processor
324 Memory
326 Program
330 Network

What is claimed is:

1. A method for displaying information in a semiconductor manufacturing apparatus comprising steps for:
obtaining a single piece or plural pieces of time-series measured data relating to processing of a substrate in the semiconductor manufacturing apparatus;
obtaining one or plural statistical values by applying statistical processing to the single piece or plural pieces of time-series measured data;
based on selection of a single statistical value from the one or plural statistical values, identifying a statistical processing condition that was used in statistical processing performed for obtaining the selected single statistical value; and
displaying the identified statistical processing condition.

2. The method as recited in claim 1, wherein:
the step for obtaining the one or plural statistical values comprises steps for
reading the statistical processing condition from a setting file in which the statistical processing condition used for calculating the statistical value from the time-series measured data has been described, and
calculating the statistical value from the time-series measured data, by using the statistical processing condition read from the setting file; and
the step for identifying the statistical processing condition comprises a step for
obtaining, from the setting file, the statistical processing condition corresponding to the statistical processing used for obtaining the selected single statistical value.

3. The method as recited in claim 1 further comprising a step for displaying, in a selectable manner, the one or plural statistical values.

4. The method as recited in claim 3, wherein display of the one or plural statistical values includes display for showing whether each of the one or plural statistical values is abnormal.

5. The method as recited in claim 1, wherein the step for displaying the identified statistical processing condition comprises a step for displaying, on a single screen, the identified statistical processing condition and the time-series measured data corresponding to the selected single statistical value.

6. The method as recited in claim 2 further comprising steps for
receiving correction with respect to the displayed statistical processing condition, and
updating the setting file based on the correction.

7. The method as recited in claim 1, wherein the statistical processing condition comprises at least one of i) a calculation formula that is used when performing the statistical processing and ii) a data range of the time-series measured data that are determined as objects of the statistical processing.

8. The method as recited in claim 7, wherein displaying the statistical processing condition comprises displaying each of the calculation formula and the data range as that having one of a mathematically represented form and a program code form.

9. A computer program product comprising computer executable instructions constructed to make a computer implement the method recited in claim 1 when the computer executable instructions are executed by a processor in the computer.
